(19) United States
(12) Patent Application Publication
(10) Pub. No.: US 2016/0226486 A1
(43) Pub. Date: Aug. 4, 2016

(54) SEMICONDUCTOR DEVICE AND SEMICONDUCTOR RELAY USING SAME

(71) Applicant: PANASONIC INTELLECTUAL PROPERTY MANAGEMENT CO., LTD., Osaka (JP)

(72) Inventors: Takuya SUNADA, Osaka (JP); Yasushi KONISHI, Osaka (JP); Yu BUNGI, Osaka (JP); Yasuyoshi ASAI, Nara (JP); Sachiko MUGIUDA, Osaka (JP)

(21) Appl. No.: 15/022,443

(22) PCT Filed: Sep. 16, 2014
(86) PCT No.: PCT/JP2014/004750

§ 371 Date: Mar. 16, 2016

(30) Foreign Application Priority Data
Sep. 19, 2013 (JP) 2013-194502

(51) Int. Cl. H03K 17/689

(52) U.S. Cl. CPC H03K 17/689

(57) ABSTRACT

A semiconductor device includes an input circuit, an output circuit, an insulation circuit, and a semiconductor substrate. The insulation circuit includes at least one capacitor for electrically insulating the input circuit and the output circuit from each other. The at least one capacitor has two electrodes, one of which being electrically connected to the input circuit, and the other of which being electrically connected to the output circuit. The semiconductor device further includes an insulation film that is made of dielectric material and is provided between the at least one capacitor and the semiconductor substrate in a thickness direction of the semiconductor substrate.

### TECHNICAL FIELD

The present invention relates generally to semiconductor devises and, more particularly, to a semiconductor device for electrically insulating an input and an output thereof from each other, and a semiconductor relay including the semiconductor device.

### BACKGROUND ART

There has been known a semiconductor relay for electrically insulating an input and an output from each other by use of a capacitor, and Document 1 (JP 2012-124807 A) discloses an example of such a semiconductor relay. The semiconductor relay described in Document 1 includes: an oscillator circuit configured to oscillate in response to input signals to generate signals; a voltage booster circuit configured to receive the signals of the oscillator circuit to generate a voltage; a charge-discharge circuit configured to charge and discharge the voltage generated by the voltage booster circuit; and an output circuit connected to the charge-discharge circuit. In the semiconductor relay described in Document 1, the oscillator circuit, the voltage booster circuit, and the charge-discharge circuit are formed on a single dielectric separation substrate and are integrated into one chip. These circuits are separated by a dielectric separation region, and are electrically connected through a wiring layer(s) or a diffusive region(s).

In the semiconductor relay described in Document 1, to achieve electrical insulation between the input and the output of the semiconductor relay, a capacitor having a high dielectric strength is used as a capacitor of the voltage booster circuit and the dielectric separation substrate in which silicon substrate regions where the circuits are formed are separated from each other is used.

However, in the conventional example described above, to ensure a dielectric strength (dielectric withstanding voltage) sufficient for keeping electrical insulation between the circuits, a region, on which the capacitor is formed, of the dielectric separation substrate (semiconductor substrate) is enclosed by the dielectric separation region. In the conventional example, therefore, an area of a region of the substrate available for forming the capacitor is limited. Accordingly, in the conventional example, the semiconductor substrate is required to have a large size in order to provide a capacitor that can offer a sufficient dielectric withstanding voltage for keeping electrical insulation between the input and the output. This leads to a problem downsizing the semiconductor substrate is difficult.

### SUMMARY OF THE INVENTION

The present invention is achieved in view of the above circumstances, and objective thereof is to provide a semiconductor device capable of downsizing a semiconductor substrate thereof and a semiconductor relay including the semiconductor device.

A semiconductor device according to an aspect of the present invention includes an input circuit, an output circuit, an insulation circuit, and a semiconductor substrate. The insulation circuit includes at least one capacitor for electrically insulating the input circuit and the output circuit from each other. The input circuit, the output circuit, and the insulation circuit are formed on the semiconductor substrate. The at least one capacitor has two electrodes, one of the two electrodes being electrically connected to the input circuit, and an other of the two electrodes being electrically connected to the output circuit. The semiconductor device further includes an insulation film that is made of dielectric material and is provided between the at least one capacitor and the semiconductor substrate in a thickness direction of the semiconductor substrate.

A semiconductor relay according to an aspect of the present invention includes the semiconductor device and a switching device. The semiconductor device is configured to output a drive signal from the output circuit in response to an input signal input to the input circuit. The switching device is configured to be turned on and off in accordance with the drive signal.

### BRIEF DESCRIPTION OF THE DRAWINGS

FIG. 1A is a schematic front view of a semiconductor device according to an embodiment, and FIG. 1B is a schematic cross-section of the semiconductor device according to the embodiment.

FIG. 2 is a schematic circuit diagram of a semiconductor relay according to the embodiment.

FIG. 3 is a schematic overall view of the semiconductor relay according to the embodiment.

FIG. 4A is a schematic front view of a semiconductor device according to a comparative example, and FIG. 4B is a schematic cross-section of the semiconductor device according to the comparative example.

### DESCRIPTION OF EMBODIMENTS

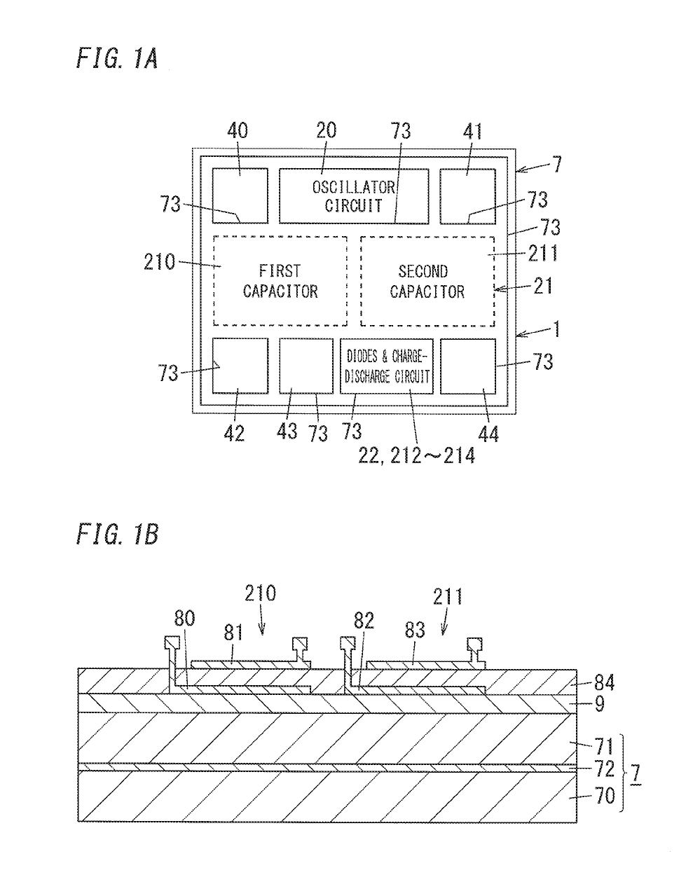

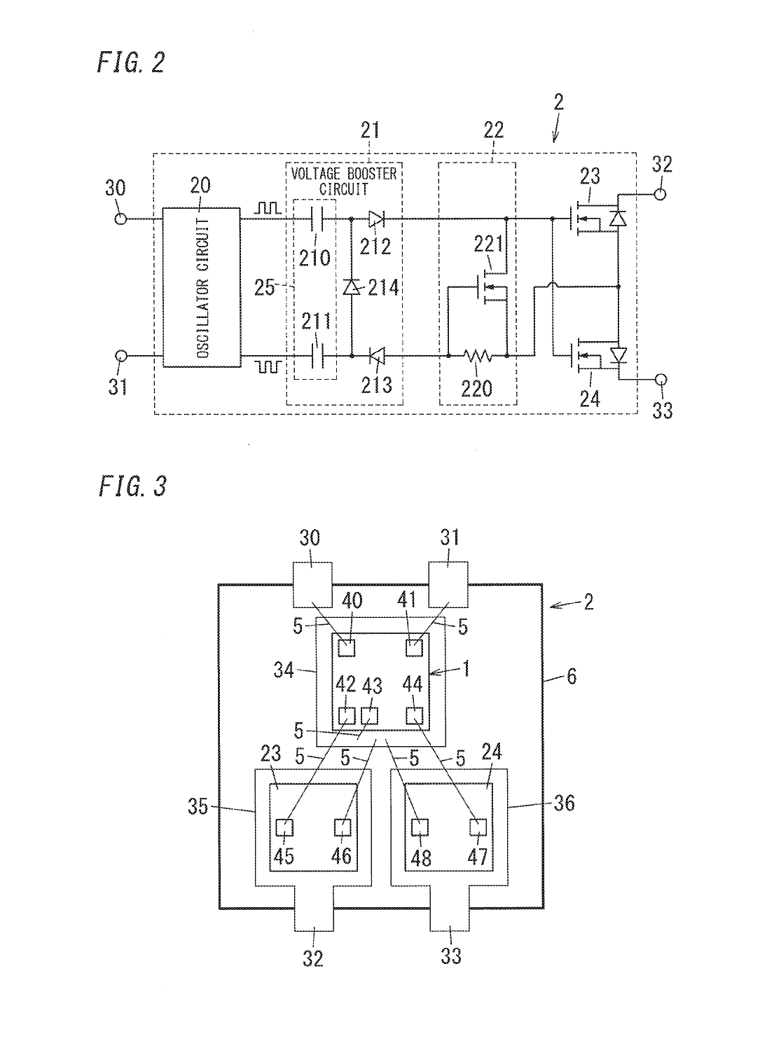

Hereinbelow, a semiconductor device 1 according to an embodiment of the present invention and a semiconductor relay 2 according to the embodiment of the present invention are described specifically with reference to drawings. As shown in FIG. 2, the semiconductor relay 2 includes a first input terminal 30, a second input terminal 31, an oscillator circuit 20, a voltage booster circuit 21, a charge-discharge circuit 22, a first MOSFET 23, a second MOSFET 24, a first output terminal 32, and a second output terminal 33. The first MOSFET 23 is formed on a single semiconductor substrate, and the second MOSFET 24 is formed on another single semiconductor substrate. As shown in FIG. 1A and FIG. 1B, the semiconductor device 1 includes a semiconductor integrated circuit including the oscillator circuit 20, the voltage booster circuit 21, and the charge-discharge circuit 22 that are integrally formed on a single semiconductor substrate 7. As shown in FIG. 3, the semiconductor relay 2 is formed by mounting the semiconductor device 1 and the MOSFETs 23 and 24 on respective die pads 34, 35, and 36, and then sealing the die pads 34, 35, and 36 in a package 6 made of ceramics or molded resin. Namely, the semiconductor relay 2 includes the semiconductor device 1 and the MOSFETs 23 and 24. Note that “MOSFET” is an abbreviation for “Metal-Oxide-Semiconductor Field-Effect Transistor”.

Initially, the circuits constituting the semiconductor relay 2 of the present embodiment are explained.

The oscillator circuit 20 is an RC oscillator circuit, for example. As shown in FIG. 2, the oscillator circuit 20 starts oscillations when a voltage is applied between the first input terminal 30 and the second input terminal 31 (that is, when receiving an input signal). As a result of the start of the oscillations, the oscillator circuit 20 generates an AC voltage (pulses). The oscillator circuit 20 stops the oscillations when the application of the voltage between the first input terminal 30 and the second input terminal 31 is stopped (that is, when the supply of the input signal is stopped). As a result of the stop of the oscillations, the oscillator circuit 20 stops generating the AC voltage.

As shown in FIG. 2, the voltage booster circuit 21 includes a first capacitor 210, a second capacitor 211, a first diode 212, a second diode 213, and a third diode 214. A cathode of the third diode 214 is electrically connected to an output side end of the first capacitor 210, and an anode of the third diode 214 is electrically connected to an output side end of the second capacitor 211. An anode of the first diode 212 is electrically connected to the output side end of the first capacitor 210 and the cathode of the third diode 214. A cathode of the second diode 213 is electrically connected to the output side end of the second capacitor 211 and the anode of the third diode 214.

The pulses generated by the oscillator circuit 20 are input to the first capacitor 210. While, the pulses pass through an inverter included in the oscillator circuit 20, and then are input to the second capacitor 211. Therefore, the pulses input to the first capacitor 210 and the pulses input to the second capacitor 211 are in antiphase. The first capacitor 210 transmits only the AC components of the input pulses to the output side, and blocks the DC components of the input pulses. The second capacitor 211 transmits only the AC components of the input pulses having the inverted phase to the output side, and blocks the DC components of the input pulses. The first capacitor 210 and the second capacitor 211 receive, from the oscillator circuit 20, pulses in antiphase, and as a result the voltage booster circuit 21 boosts up the pulses and outputs a resultant voltage. In the semiconductor relay 2 of the present embodiment, the voltage booster circuit 21 includes the Dickson charge pump circuit.

As shown in FIG. 2, the charge-discharge circuit 22 includes a resistor 220 and a depletion-type MOSFET (hereinafter, referred to as “D-type MOSFET”) 221. The resistor 220 is electrically connected between a gate electrode and a source electrode of the D-type MOSFET 221. The gate electrode and a drain electrode of the D-type MOSFET 221 are electrically connected to two output terminals of the voltage booster circuit 21, respectively. The drain electrode of the D-type MOSFET 221 is electrically connected to gate electrodes of the first MOSFET 23 and the second MOSFET 24. The source electrode of the D-type MOSFET 221 is electrically connected to source electrodes of the first MOSFET 23 and the second MOSFET 24.

When a voltage is applied from the voltage booster circuit 21, a current flows from the voltage booster circuit 21 to the resistor 220 through the D-type MOSFET 221. As a result, a voltage drop occurs between both ends of the resistor 220, and the D-type MOSFET is turned off due to the voltage drop. Accordingly, drain-source impedance of the D-type MOSFET 221 becomes high. In summary, when a voltage is applied from the voltage booster circuit 21, the charge-discharge circuit 22 charges gate capacitors of the first MOSFET 23 and the second MOSFET 24.

When the application of the voltage from the voltage booster circuit 21 is stopped, a flow of the current from the voltage booster circuit 21 to the resistor 220 and the D-type MOSFET 221 is stopped. As a result, the voltage drop between the both ends of the resistor 220 disappears, and the D-type MOSFET is turned on. Accordingly, the drain-source impedance of the D-type MOSFET 221 becomes low. In short, when the application of the voltage from the voltage booster circuit 21 is stopped, the charge-discharge circuit 22 discharges electric charges stored in the gate capacitors of the first MOSFET 23 and the second MOSFET 24. Note that the “gate capacitor” means a capacitor (called “input gate capacitor”) existing between a gate electrode and a source electrode of a MOSFET and a capacitor (called “output gate capacitor”) existing between a gate electrode and a drain electrode of a MOSFET.

The first MOSFET 23 and the second MOSFET 24 are electrically connected in series so that source electrodes thereof are electrically connected to each other. A drain electrode of the first MOSFET 23 is electrically connected to the die pad 35. Part of the die pad 35 is exposed to an outside of the package 6, and serves as the first output terminal 32 (see FIG. 3). As shown in FIG. 3, a gate electrode of the first MOSFET 23 is electrically connected to a first gate pad 45. As shown in FIG. 3, the source electrode of the MOSFET 23 is electrically connected to a first source pad 46.

A drain electrode of the second MOSFET 24 is electrically connected to the die pad 36. Part of the die pad 36 is exposed to an outside of the package 6, and serves as the second output terminal 33 (see FIG. 3). As shown in FIG. 3, a gate electrode of the second MOSFET 24 is electrically connected to a second gate pad 47. As shown in FIG. 3, a source electrode of the second MOSFET 24 is electrically connected to a second source pad 48.

Hereinbelow, an operation of the semiconductor relay 2 is explained. When a voltage is applied between the first input terminal 30 and the second input terminal 31, the oscillator circuit 20 starts the oscillations to generate pulses. The voltage booster circuit 21 boosts up the pulses supplied from the oscillator circuit 20 to output a resultant voltage. The output voltage of the voltage booster circuit 21 is applied to the charge-discharge circuit 22, and the charge-discharge circuit 22 charges the gate capacitors of the MOSFETs 23 and 24. As a result, the MOSFETs 23 and 24 are turned on to electrically connect the first output terminal 32 and the second output terminal 33 with each other. The semiconductor relay 2 is turned on accordingly.

When the application of the voltage between the first input terminal 30 and the second input terminal 31 is stopped, the oscillator circuit 20 stops the oscillations, and thus the voltage booster circuit 21 stops outputting the voltage. Then, the electric charges stored in the gate capacitors of the MOSFETs 23 and 24 are discharged through the charge-discharge circuit 22. As a result, the MOSFETs 23 and 24 are turned off, and the electrical connection between the first output terminal 32 and the second output terminal 33 is broken. The semiconductor relay 2 is turned off accordingly.

The structure of the semiconductor device 1 of the present embodiment is explained next. Hereinafter, one surface, on which the oscillator circuit 20 and the like are formed, of the semiconductor substrate 7 in a thickness direction thereof (top-bottom direction in FIG. 1B) is referred to as “main surface”. As shown in FIG. 1A, in the semiconductor device 1, the oscillator circuit 20, the voltage booster circuit 21, and the charge-discharge circuit 22 are formed on the main surface of the semiconductor substrate 7. These circuits are electrically connected together through a wiring layer(s) or a diffusion region(s).

The semiconductor substrate 7 is a so-called Silicon On Insulator (SOI) substrate, and includes a support substrate 70, an active layer 71, and an insulation layer (buried oxide film) 72, as shown in FIG. 1B. The support substrate 70 is a silicon substrate (Si substrate) made of monocrystalline silicon. The insulation layer 72 is provided on one surface, in a thickness direction, of the support substrate 70. The insulation layer 72 is made of a silicon oxide film. The active layer 71 is provided on one surface, in a thickness direction, of the insulation layer 72. The active layer 71 is made of monocrystalline silicon. The support substrate 70 and the active layer 71 are electrically insulated from each other by the insulation layer 72.

The semiconductor device 1 includes first and second pads 40 and 41 electrically connected to the input terminals of the oscillator circuit 20. The first and second pads 40 and 41 are formed on the main surface of the semiconductor substrate 7. The semiconductor device 1 includes a third pad 42, a fourth pad 43, and a fifth pad 44 which are electrically connected to the output terminals of the charge-discharge circuit 22. The third pad 42, the fourth pad 43, and the fifth pad 44 are formed on the main surface of the semiconductor substrate 7.

As shown in FIG. 3, the first pad 40 and the first input terminal 30 are electrically connected through a bonding wire 5. The second pad 41 and the second input terminal 31 are electrically connected through another bonding wire 5. The third pad 42 and the first gate pad 45 are electrically connected through another bonding wire 5. The fifth pad 44 and the second gate pad 47 are electrically connected through another bonding wire 5. The fourth pad 43 is electrically connected to the die pad 34 through another bonding wire 5. The die pad 34 and the first source pad 46 are electrically connected through another bonding wire 5. The die pad 34 and the second source pad 48 are electrically connected through another bonding wire 5.

As shown in FIG. 1A, the diodes 212 to 214 of the voltage booster circuit 21 and the charge-discharge circuit 22 are collectively formed on the main surface of the semiconductor substrate 7. The capacitors 210 and 211 of the voltage booster circuit 21 are formed on the main surface of the semiconductor substrate 7 at regions between the oscillator circuit 20 and a group of the diodes 212 to 214 and the charge-discharge circuit 22.

As shown in FIG. 1B, the first capacitor 210 includes: a first electrode 80 electrically connected to an input circuit; and a second electrode 81 electrically connected to an output circuit. As shown in FIG. 1B, the second capacitor 211 includes: a first electrode 82 electrically connected to the input circuit; and a second electrode 83 electrically connected to the output circuit. In other words, with regard to each of the capacitors 210 and 211, the first electrode 80, 82, which is one of two electrodes thereof, is electrically connected to the input circuit, while the second electrode 81, 83, which is the other of the two electrodes thereof, is electrically connected to the output circuit. The electrodes 80 to 83 are made of aluminum or polysilicon (highly pure polycrystalline silicon), for example. A dielectric layer 84 is provided between the first electrode 80, 82 and the second electrode 81, 83. The dielectric layer 84 is made of dielectric material such as silicon dioxide (silica) and silicon nitride, for example.

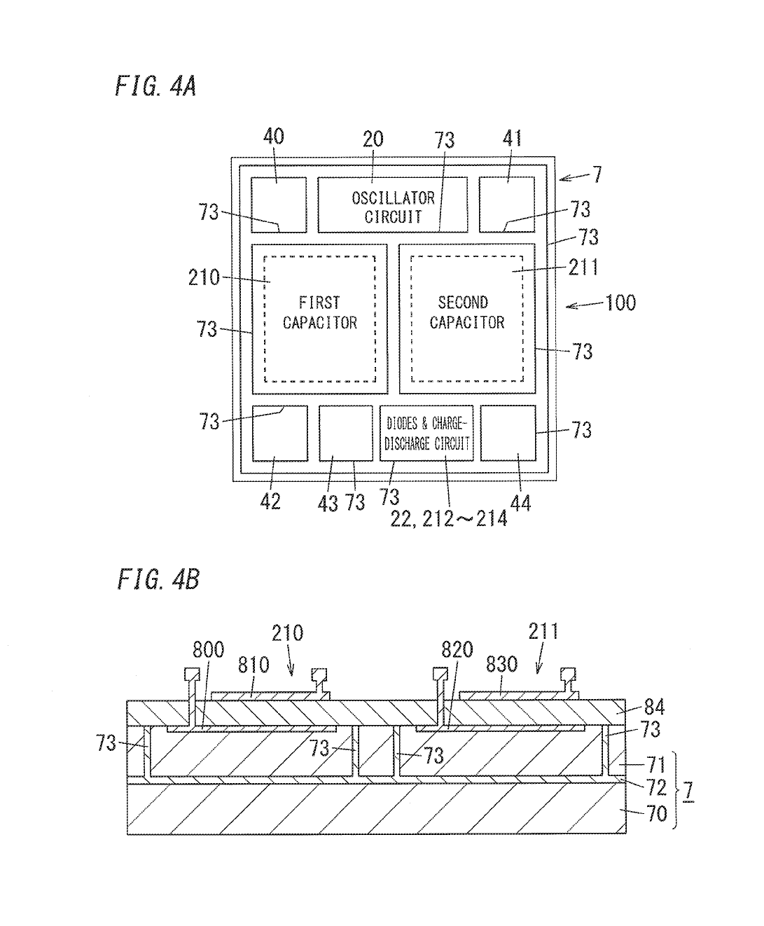

As shown in FIG. 1A, a dielectric separation region 73 is formed around the oscillator circuit 20 in the semiconductor substrate 7 to electrically insulate the oscillator circuit 20 from around regions. The dielectric separation region 73 may be formed by: boring the semiconductor substrate 7 in the thickness direction thereof to form a trench; forming a silicon oxide film on inner faces of the trench; and filling a space surrounded by the silicon oxide film with polycrystalline silicon, for example. The trench has a depth so as to extend from the main surface of the semiconductor substrate 7 to the insulation layer 72 (see FIG. 4B). Also, another dielectric separation region 73 is formed around the group of the diodes 212 to 214 and the charge-discharge circuit 22. Further, other dielectric separation regions 73 are formed around the pads 40 to 44, respectively.

In the semiconductor relay 2, it is necessary to keep electrical insulation between the input and the output. To keep electrical insulation between the input and the output of the semiconductor relay 2, it is necessary to design the semiconductor device 1 such that each of the capacitors 210 and 211 of the voltage booster circuit 21 has a dielectric withstanding voltage that is equal to or greater than a dielectric withstanding voltage required for keeping electrical insulation between the input and the output of the semiconductor relay 2. That is, the capacitors 210 and 211 function as at least part of an insulation circuit 25 for electrically insulating the input circuit and the output circuit from each other.

In the semiconductor device 1, the oscillator circuit 20, the voltage booster circuit 21, and the charge-discharge circuit 22 are formed on the main surface of the single semiconductor substrate 7. Therefore, the semiconductor device 1 should satisfy a condition that a dielectric withstanding voltage of a region interposed between the input circuit (oscillator circuit 20) and the output circuit (diodes 212 to 214 and charge-discharge circuit 22) without including the capacitors 210 and 211 is equal to or greater than the dielectric withstanding voltage required for keeping electrical insulation between the input and the output of the semiconductor relay 2.

FIG. 4A and FIG. 4B show a semiconductor device 100, which is a comparative example of the semiconductor device 1 of the present embodiment, and is designed so as to satisfy the above condition. In the semiconductor device 100, dielectric separation regions 73 are formed in order to electrically insulate first electrodes 800, 820 from the input circuit as well as the output circuit. In the semiconductor device 100, an active layer 71 includes regions which are doped with impurities at high concentration to serve as the first electrodes 800 and 820 of capacitors 210 and 211. Also, second electrodes 810 and 830 are made of aluminum or polysilicon, for example. In the semiconductor device 100, the dielectric separation regions 73 are formed around the respective capacitors 210 and 211. Therefore, the semiconductor device 100 has a problem that an area of a region of the semiconductor substrate 7 available for forming the capacitor 210, 211 is limited.

In this regard, in the semiconductor device 1 of the present embodiment, an insulation film 9 is provided between the semiconductor substrate 7 and the capacitors 210 and 211 in the thickness direction of the semiconductor substrate 7, as shown in FIG. 1B. The insulation film 9 is made of dielectric material such as silicon dioxide (silica) and silicon nitride, for example. The insulation film 9 works to electrically insulate the input circuit and the output circuit from each other.

As described above, the semiconductor device 1 of the present embodiment includes the insulation film 9 provided between the semiconductor substrate 7 and the capacitors 210 and 211, and accordingly is capable of ensuring the dielectric withstanding voltage of a region interposed between the input circuit and the output circuit without including the capacitors 210 and 211. Therefore, the semiconductor device 1 of the present embodiment does not necessarily include dielectric separation regions 73 formed around the capacitors 210 and 211, in contrast to the semiconductor device 100. Accordingly, in the semiconductor device 1 of the present embodiment, an area of a region of the semiconductor substrate 7 available for forming the capacitor 210, 211 can be made to be larger than that in the semiconductor device 100, and thus the semiconductor substrate 7 can be downsized. According to the semiconductor device 1 of the present embodiment, the semiconductor substrate 7 can be downsized, and accordingly the cost of the semiconductor substrate 7 can be reduced.

In the semiconductor device 1 of the present embodiment, the insulation film 9 covers a whole of the main surface of the semiconductor substrate 7. However, it is sufficient that the insulation film 9 may be provided to at least regions, on which the capacitors 210 and 211 are to be formed, of the semiconductor substrate 7.

The insulation film 9 may have a dielectric withstanding voltage that is equal to or greater than a dielectric withstanding voltage of the capacitor 210, 211. According to this configuration, the dielectric withstanding voltage required for keeping electrical insulation between the input circuit and the output circuit can be ensured by the insulation film 9 only. In an example, it is assumed that the dielectric withstanding voltage required for keeping electrical insulation between the input circuit and the output circuit is 600 V. In this case, it is sufficient that the insulation film 9 be made of silicon nitride, and has a thickness (thickness of the insulation film 9) of 1 μm or more, for example.

The semiconductor device 1 of the present embodiment may further include an insulation part for electrically insulating a region, on which the capacitors 210 and 211 are formed, of the semiconductor substrate 7, from other regions, on which the input circuit and the output circuit are formed, of the semiconductor substrate 7. In the semiconductor device 1 of the present embodiment, the dielectric separation regions 73 around the oscillator circuits 20 and the like shown in FIG. 1A serve as the insulation part. In this configuration, the dielectric withstanding voltage of a region interposed between the input circuit and the output circuit without including the capacitors 210 and 211 may be ensured by the dielectric withstanding voltage of the insulation part and the dielectric withstanding voltage of the insulation film 9 in total. In this configuration, therefore, the insulation film 9 can be made to be thin, compared to a case where the dielectric withstanding voltage is ensured by the insulation film 9 only.

The insulation film 9 may have a thickness determined based on the dielectric withstanding voltage required for keeping electrical insulation between the input circuit and the output circuit.

As described above, the semiconductor relay 2 of the present embodiment includes the semiconductor device 1 and the MOSFETs 23 and 24 (switching devices). The semiconductor device 1 is configured to output a voltage (drive signal) from the diodes 212 to 214 and the charge-discharge circuit 22 (output circuit) in response to a voltage (input signal) input to the oscillator circuit 20 (input circuit). The switching device is configured to be turned on and off in accordance with the drive signal. The semiconductor relay 2 of the present embodiment includes the semiconductor device 1 that can offer size and cost reduction of the semiconductor substrate 7, and accordingly the size and cost of the relay can be reduced as well.

In the semiconductor device 1 of the present embodiment, the first electrodes 80 and 82 of the capacitors 210 and 211 are electrically connected to the input circuit while the second electrodes 81 and 83 thereof are electrically connected to the output circuit, however, the input circuit and the output circuit can be interchanged. That is, the first electrodes 80 and 82 may be electrically connected to the output circuit while the second electrodes 81 and 83 may be electrically connected to the input circuit. In the semiconductor device 1 of the present embodiment, the semiconductor substrate 7 is an n-type substrate, but alternatively may be a p-type substrate. In the semiconductor relay 2 of the present embodiment, the switching device is a MOSFET, but may be another kind of switching device such as Insulated Gate Bipolar Transistor (IGBT).

As described above, a semiconductor device 1 of the present embodiment includes the following first feature.

In the first feature, the semiconductor device 1 includes an input circuit (oscillator circuit 20), an output circuit (diodes 212 to 214 and charge-discharge circuit 22), an insulation circuit 25, and a semiconductor substrate 7. The insulation circuit 25 includes at least one capacitor (first capacitor 210, second capacitor 211) for electrically insulating the input circuit and the output circuit from each other. The input circuit, the output circuit, and the insulation circuit 25 are formed on the semiconductor substrate 7. The at least one capacitor has two electrodes, one (first electrode 80, 82) of the two electrodes is electrically connected to the input circuit, and the other (second electrode 81, 83) of the two electrodes is electrically connected to the output circuit. The semiconductor device 1 further includes an insulation film 9 that is made of dielectric material and is provided between the at least one capacitor and the semiconductor substrate 7 in a thickness direction of the semiconductor substrate 7.

The semiconductor device 1 of the present embodiment may include the following second feature, realized in combination with the first feature.

In the second feature, the insulation film 9 has a dielectric withstanding voltage that is equal to or greater than a dielectric withstanding voltage of the at least one capacitor.

The semiconductor device 1 of the present embodiment may include the following third feature, realized in combination with the first or second feature.

In the third feature, the semiconductor device 1 further includes an insulation part (dielectric separation region 73). The insulation part electrically insulates a region, on which the at least one capacitor is formed, of the semiconductor substrate 7, from other regions, on which the input circuit and the output circuit are formed, of the semiconductor substrate 7.

The semiconductor device 1 of the present embodiment may include the following fourth feature, realized in combination with any one of the first to third features.

In the fourth feature, the insulation film 9 has a thickness determined based on a dielectric withstanding voltage required for keeping electrical insulation between the input circuit and the output circuit.

The semiconductor relay 2 of the present embodiment includes the following fifth feature.

In the fifth feature, the semiconductor relay 2 includes the semiconductor device 1 of any one of the first to fourth feature and a switching device (first MOSFET 23, second MOSFET 24). The semiconductor device 1 is configured to output a drive signal from the output circuit in response to an input signal input to the input circuit. The switching device is configured to be turned on and off in accordance with the drive signal.

In the semiconductor device 1 and the semiconductor relay 2 of the present embodiment, the insulation film 9 is provided between the semiconductor substrate 7 and the at least one capacitor, and accordingly a dielectric withstanding voltage of a region interposed between the input circuit and the output circuit without including at least one capacitor can be ensured. Therefore, the semiconductor device 1 and the semiconductor relay 2 of the present embodiment need not include dielectric separation regions formed around the at least one capacitor, in contrast to conventional ones. Accordingly, in the semiconductor device 1 and the semiconductor relay 2 of the present embodiment, an area of a region of the semiconductor 7 available for forming the capacitor can be increased relative to the conventional example, and thus the semiconductor substrate 7 can be downsized.

1. A semiconductor device, comprising:
an input circuit;
an output circuit;
an insulation circuit including at least one capacitor for electrically insulating the input circuit and the output circuit from each other; and
a semiconductor substrate on which the input circuit, the output circuit, and the insulation circuit are formed,
the at least one capacitor having two electrodes, one of the two electrodes being electrically connected to the input circuit, and an other of the two electrodes being electrically connected to the output circuit, and
the semiconductor device further comprising an insulation film that is made of dielectric material and is provided between the at least one capacitor and the semiconductor substrate in a thickness direction of the semiconductor substrate.

2. The semiconductor device of claim 1, wherein
the insulation film has a dielectric withstanding voltage that is equal to or greater than a dielectric withstanding voltage of the at least one capacitor.

3. The semiconductor device of claim 2, further comprising an insulation part for electrically insulating a region, on which the at least one capacitor is formed, of the semiconductor substrate, from other regions, on which the input circuit and the output circuit are formed, of the semiconductor substrate.

4. The semiconductor device of claim 3, wherein
the insulation film has a thickness determined based on a dielectric withstanding voltage required for keeping electrical insulation between the input circuit and the output circuit.

5. A semiconductor relay comprising:
the semiconductor device of claim 1; and
a switching device,
the semiconductor device being configured to output a drive signal from the output circuit in response to an input signal input to the input circuit, and
the switching device being configured to be turned on and off in accordance with the drive signal.

6. A semiconductor relay comprising:
the semiconductor device of claim 2; and
a switching device,
the semiconductor device being configured to output a drive signal from the output circuit in response to an input signal input to the input circuit, and
the switching device being configured to be turned on and off in accordance with the drive signal.

7. A semiconductor relay comprising:
the semiconductor device of claim 3; and
a switching device,
the semiconductor device being configured to output a drive signal from the output circuit in response to an input signal input to the input circuit, and
the switching device being configured to be turned on and off in accordance with the drive signal.

8. A semiconductor relay comprising:
the semiconductor device of claim 4; and
a switching device,
the semiconductor device being configured to output a drive signal from the output circuit in response to an input signal input to the input circuit, and
the switching device being configured to be turned on and off in accordance with the drive signal.
